(19) United States
(12) Patent Application Publication
(10) Pub. No.: US 2005/0012175 A1
(43) Pub. Date: Jan. 20, 2005

(54) Semiconductor substrate and manufacturing process therefor

(76) Inventor: Kazuhiro Tsuruta, Nishio-shi (JP)

Correspondence Address: POSZ & BETHARDS, PLC, 11250 ROGER BACON DRIVE, SUITE 10, RESTON, VA, 20190, US

(21) Appl. No.: 10/699,831

(22) Filed: Nov. 4, 2003

(30) Foreign Application Priority Data
Jun. 4, 2003 (JP) 2003-159888
Nov. 12, 2002 (JP) 2002-328605

(51) Int. Cl. H01L 21/8234; H01L 21/8244

(52) U.S. Cl. 257/531; 438/238

(57) ABSTRACT

In a semiconductor substrate for use in a semiconductor device in which first device components are disposed on an insulating material and second device components are fabricated, a thermal-oxide layer of 10 μm or more in thickness is formed in a region where the first device components are to be disposed, and a groove packed with a polycrystalline semiconductor is formed at an inward position from the peripheral edge of the thermal-oxide layer and along the same peripheral edge. A process for manufacturing this semiconductor substrate is also disclosed.

### BACKGROUND OF THE INVENTION

1. Field of the Invention

This invention relates to a semiconductor substrate and a process for manufacturing the same.

2. Description of the Prior Art

With spread of miniature wireless information machinery such as cellular telephones, development is in progress on monolithic ICs in which active components and passive components are integrated on a semiconductor substrate to make circuits into one chip. Stated specifically, active components such as transistors and diodes and passive components such as capacitors and inductors are integrated on a semiconductor substrate to make circuits such as high-frequency oscillators, amplifiers and filters into one chip.

However, where inductors are formed on a semiconductor substrate, there is a problem that parasitic capacitance and parasitic resistance (eddy current loss) may come about between conductors constituting the inductors and the semiconductor substrate, as reported in a J. Y. C. Chang et al.'s paper “Large Suspended Inductors on Silicon and Their Use in a 2-μm CMOS RF Amplifier”, IEEE Electron Device Letters, Vol.14, No.5, pp.246-248 (1993) (hereinafter “Non-patent Literature 1). Accordingly such parasitic capacitance and parasitic resistance must be reduced in order to obtain an inductor with high quality factor (Q).

As a method for solving this problem, in Non-patent Literature 1, a method is proposed in which a groove (hollow) is formed under inductors on the semiconductor substrate surface. However, the solution method disclosed in Non-patent Literature 1 has the following two problems. The first is that the process of removing silicon under the inductor by etching is incompatible with conventional silicon LSI processes. The second is a problem that in the above structure the inductor is formed in suspended wiring structure and hence no sufficient strength is achievable.

Accordingly, as a means for solving the above problems, it is proposed in Japanese Patent Application Laid-open No. 2001-77315 (hereinafter “Patent Literature 1” to form a groove of 20 μm or more in depth at some part of the semiconductor substrate, fill the groove with an insulating material, and then form a passive component such as an inductor on the insulating material. This enable reduction of parasitic capacitance and parasitic resistance between a conductor constituting the capacitance and the semiconductor substrate, and at the same time enables assimilation to conventional silicon LSI processes, also making it possible to secure sufficient strength.

However, the method disclosed in Patent Literature 1, makes use of an organic insulating fluid as the insulating material, and has the following problem. Usually, such an insulating fluid causes a volumetric change (volumetric contraction) when it solidifies, bringing about problems that it is difficult to make substantially equal the height of the semiconductor substrate surface for forming active components and that of the insulating material region surface for forming passive components or to make flat the insulating material region surface, and that stress is applied to the substrate because of the volumetric change to cause the substrate to warp.

In a C. Zhang et al.'s paper “FABRICATION OF THICK SILICON DIOXIDE LAYERS USING DRIE, OXIDATION AND TRENCH REFILL”, Technical Digest of The Fifteenth IEEE International Conference on Micro Electro Mechanical Systems, pp.160-163 (2003) or a H. Jiang et al.'s paper “REDUCING SILICON-SUBSTRATE PARASITICS OF ON-CHIP TRANSFORMERS”, Technical Digest of The Fifteenth IEEE International Conference on Micro Electro Mechanical Systems, pp.649-652 (2002), the following method is also disclosed. A plurality of grooves of 10 μm or more in depth are formed on one side of a silicon substrate. Then, columns (walls) in the silicon substrate held between grooves are completely oxidized by thermal oxidation and also an oxide is deposited in the remaining grooves to fill out the grooves to form a thick insulating material region of 10 μm or more in thickness in the silicon substrate. However, in this method as well, like difficulties may arise if heat treatment at 800° C. or more is repeated when active components are formed on the substrate in which such a thick insulating material region has been formed. That is, stress is applied to the silicon substrate because of a difference in coefficient of thermal expansion between the silicon substrate and the silicon oxide (silicon: 2.5×10⁻⁶/° C.; silicon oxide: 0.5×10⁻⁶/° C.) to cause the silicon substrate to warp. In addition, crystal defects and dislocation may come about to make inoperable the active components formed in the silicon substrate region. In particular, such crystal defects and dislocation may concentrate in the silicon substrate region vicinal to the thick insulating material region. Hence, in order to prevent the active components from coming inoperable, the active components must be separated from the insulating material region at a stated distance (e.g., tens of μm), and such areas serve as dead spaces to lower the degree of integration of circuits.

### SUMMARY OF THE INVENTION

The present invention was made under such circumstances. Accordingly, an object of the present invention is to provide a semiconductor substrate which can make device components well exhibit their functions, also has an insulating layer thick enough to obtain sufficient strength, and can not easily cause substrate warpage, crystal defects and dislocation, promising materialization of highly integrated circuits, and to provide a process for manufacturing such a semiconductor substrate.

To achieve the above objects, the present invention provides a semiconductor substrate for use in a semiconductor device in which first device components (5) are disposed on an insulating material and second device components (Q1, Q2) are fabricated, wherein;
a thermal-oxide layer (2) of 10 μm or more in thickness is formed in a region (A1) where the first device components are to be disposed, and a groove (3) packed with a polycrystalline semiconductor (4) is formed at an inward position from the peripheral edge (2a) of the thermal-oxide layer (2) and along the same peripheral edge (2a).

The present invention also provides a process for manufacturing a semiconductor substrate for use in a semiconductor device in which first device components (5) are disposed on an insulating material and second device components (Q1, Q2) are fabricated; the process comprising the steps of:
simultaneously forming, in a region (A1) in a semiconductor substrate (1) in which region the first device components (5) are to be disposed, a first groove (24) of 10 μm or more in depth and, along the perimeter of a region where the first groove (24) is to be formed, a second groove (25) having a larger groove width than the groove width the first groove (24) has;
making a thermal-oxide film (27) grow by thermal oxidation, from the inner surfaces of the first and second grooves (24, 25) to make, in the first groove (24), the groove filled with the thermal-oxide film (27) and form, in the second groove (25), the thermal-oxide film (27) on the bottom and sidewalls thereof leaving a third groove (3) therein; and
packing the third groove (3) with a polycrystalline semiconductor (4).

As another embodiment of the above manufacturing process, the present invention still also provides a process for manufacturing a semiconductor substrate for use in a semiconductor device in which first device components (5) are disposed on an insulating material and second device components (Q1, Q2) are fabricated; the process comprising the steps of:
simultaneously forming, in a region (A1) in a semiconductor substrate (1) in which region the first device components (5) are to be disposed, a plurality of first grooves (24) of 10 μm or more each in depth in the state that they stand adjacent to each other, and, along the perimeter of a region where the first grooves (24) are to be formed, a second groove (25) having a larger groove width than the groove width the first grooves (24) each have;
making a thermal-oxide film (27) grow by thermal oxidation, from the inner surfaces of the first and second grooves (24, 25) to make, in the first grooves (24), the grooves filled with the thermal-oxide film (27) and form, in the second groove (25), the thermal-oxide film (27) on the bottom and sidewalls thereof leaving a third groove (3) therein; and
packing the third groove (3) with a polycrystalline semiconductor (4).

### BRIEF DESCRIPTION OF THE DRAWINGS

FIG. 1 is a longitudinal sectional view of a semiconductor substrate according to an embodiment of the present invention.

FIG. 2 is a plan view of the semiconductor substrate shown in FIG. 1.

FIG. 3 is a longitudinal sectional view showing part of a monolithic IC according to an embodiment of the present invention.

FIG. 4 is a graph showing the results of simulation in respect of signal transmission loss and oxide film layer thickness.

FIGS. 5A, 5B and 5C are sectional views showing a process of manufacturing a semiconductor substrate for a monolithic IC.

FIGS. 6A, 6B and 6C are sectional views showing a subsequent process of manufacturing the semiconductor substrate for a monolithic IC.

FIGS. 7A and 7B are sectional views showing a subsequent process of manufacturing the semiconductor substrate for a monolithic IC.

FIG. 8 is a plan view showing a step corresponding to that shown in FIG. 6A, in the process of manufacturing the semiconductor substrate for a monolithic IC.

FIGS. 9A, 9B and 9C are sectional views showing another process of manufacturing a semiconductor substrate for a monolithic IC.

FIG. 10 is a longitudinal sectional view of a semiconductor substrate.

FIG. 11 is a longitudinal sectional view showing part of a monolithic IC in which an SOI substrate is applied.

FIG. 12 is a plan view showing a semiconductor substrate.

FIG. 13 is a plan view showing a semiconductor substrate.

FIG. 14 is a view showing a semiconductor substrate.

### DESCRIPTION OF THE PREFERRED EMBODIMENTS

The semiconductor substrate of the present invention is a semiconductor substrate for use in a semiconductor device in which first device components (passive components 5) are disposed on an insulating material and second device components (active components Q1, Q2) are fabricated, and is characterized in that a thermal-oxide layer (2) of 10 μm or more in thickness is formed in a region (A1) where the first device components are to be disposed, and a groove (3) packed with a polycrystalline semiconductor (4) is formed at an inward position from the peripheral edge (2a) of the thermal-oxide layer (2) and along the same peripheral edge (2a). This thick thermal-oxide layer enables device components to exhibit their functions sufficiently (e.g., parasitic capacitance and parasitic resistance in respect to passive components can sufficiently be reduced). Also, since the first device components are not on any suspended wiring structure, sufficient mechanical strength can be obtained. Still also, the groove packed with a polycrystalline semiconductor is formed at an inward position from, and along, the peripheral edge of the thermal-oxide layer. Hence, the polycrystalline semiconductor serves as a layer that absorbs thermal stress applied in the step of forming second device components, and hence this can keep the substrate from warping, and any crystal defects and dislocation from occurring, so that the second device components can be prevented from operating defectively. This can lessen dead spaces, and materialize highly integrated circuits.

Here, the groove (3) packed with a polycrystalline semiconductor (4) may preferably have a depth (L12) larger than the thickness (t1) of the thermal-oxide layer (2). In the case when the groove packed with the polycrystalline semiconductor has a depth larger than the thickness of the thermal-oxide layer, the thermal stress can effectively be absorbed up to the lower part of the thick thermal-oxide layer region in the step of forming device components on the semiconductor substrate. Hence, this can more keep the substrate from warping and any crystal defects and dislocation from occurring.

The above semiconductor substrate may preferably be an SOI (silicon on insulator) substrate, and the thermal-oxide layer (2) may preferably be so made up as to reach a buried oxide film layer (202) of the SOI substrate.

The first device components (5) may be passive components, and the second device components (Q1, Q2) may be active components. In particular, the present invention may preferably be applied to a case in which the passive components (5) are passive components that handle high-frequency signals.

A first embodiment of the semiconductor substrate manufacturing process of the present invention is a process for manufacturing a semiconductor substrate for use in a semiconductor device in which first device components (5) are disposed on an insulating material and second device components (Q1, Q2) are fabricated. In this process, a first groove (24) of 10 μm or more in depth and, along the perimeter of a region where the first groove (24) is to be formed, a second groove (25) having a larger groove width than the groove width the first groove (24) has are simultaneously formed in a region (A1) in a semiconductor substrate (1) in which region the first device components (5) are to be disposed. Then, a thermal-oxide film (27) is made to grow by thermal oxidation, from the inner surfaces of the first and second grooves (24, 25) to make, in the first groove (24), the groove filled with the thermal-oxide film and form, in the second groove (25), the thermal-oxide film (27) on the bottom and sidewalls thereof leaving a third groove (3) therein. Further, the third groove (3) is packed with a polycrystalline semiconductor (4). Thus, the semiconductor substrate according to the first embodiment of the present invention is obtained.

In a second embodiment of the semiconductor substrate manufacturing process of the present invention, a plurality of first grooves (24) of 10 μm or more each in depth and, along the perimeter of a region where the first grooves (24) are to be formed, a second groove (25) having a larger groove width than the groove width the first grooves (24) each have are simultaneously formed in a region (A1) in a semiconductor substrate (1) in which region the first device components (5) are to be disposed. Then, a thermal-oxide film (27) is made to grow by thermal oxidation, from the inner surfaces of the first and second grooves (24, 25) to make, in the first grooves (24), the grooves filled with the thermal-oxide film (27) and form, in the second groove (25), the thermal-oxide film (27) on the bottom and sidewalls thereof leaving a third groove (3) therein. Further, the third groove (3) is packed with a polycrystalline semiconductor (4). Thus, the semiconductor substrate according to the second embodiment of the present invention is obtained.

According to the first and second embodiments of the semiconductor substrate manufacturing process of the present invention, the third groove absorbs the stress caused by a difference in coefficient of thermal expansion between the oxide film and the semiconductor substrate when the inside(s) of the first groove(s) is/are filled with the oxide, so that no excess stress may be applied to the part of the semiconductor substrate. Hence, the substrate can be kept from warping.

In the first and second embodiments of the semiconductor substrate manufacturing process of the present invention, in the step of forming the first groove(s) (24) and the second groove (25) simultaneously, the second groove (25) may preferably be formed in a depth (L11) larger than the depth of the first groove(s) (24). In this case, the difference in coefficient of thermal expansion between the oxide film and the semiconductor substrate can effectively be absorbed up to the lower part of the thick thermal-oxide layer region in the semiconductor substrate manufacturing process. Hence, this can more keep any crystal defects and dislocation from occurring and the substrate (safer) from warping.

The step of packing the third groove (3) with a polycrystalline semiconductor (4) may preferably comprise depositing a polycrystalline semiconductor (28) on the semiconductor substrate (1) to provide the polycrystalline semiconductor (28) in the third groove (3), thereafter removing an excess polycrystalline semiconductor (28) deposited at the surface portion of the semiconductor substrate (1), and then thermally oxidizing the polycrystalline semiconductor (28) having remained in surface concavities of the semiconductor substrate (1). By doing so, any concavities at the surface portion of the thermal-oxide layer can also be filled with the polycrystalline semiconductor to make the surface flat, and, as a result of the thermal oxidation further carried out thereafter, the polycrystalline semiconductor having remained in the concavities is also oxidized to undergo volumetric expansion, so that the surface is further flattened. The thick thermal-oxide layer thus formed can have a surface substantially equal to the height of the substrate surface.

Where the groove width of the first groove (24), or each of the first grooves (24), is represented by W1, the groove width of the second groove (25) by W3, the difference in coefficient of thermal expansion between the semiconductor substrate (1) and the thermal oxide thereof by A, the maximum width of a thermal-oxide film portion that is formed around the first groove(s) accompanying thermal oxidation by W, and the difference in temperature between room temperature and maximum thermal oxidation treatment temperature by T, these may preferably satisfy the following expression:
W3>{(A·W·T)/2}+W1.
This enables the third groove to absorb any dimensional difference produced in the horizontal direction of the substrate because of the difference in coefficient of thermal expansion between the semiconductor and its oxide during the heat treatment, to reduce the stress applied to the semiconductor substrate during the heat treatment, and can keep any crystal defects and dislocation from occurring and the substrate (wafer) from warping.

In the first groove (24), or each of the first grooves (24), the aspect ratio (L1/W1) thereof which is the dimensional ratio of groove depth (L1) to groove width (W1) may preferably be 10 or more. The first groove(s) having the aspect ratio (L1/W1) of 10 or more enables the thick thermal-oxide layer to be formed in a depth of 10 μm or more at a low cost by the step of thermal oxidation of films of about 1 μm in layer thickness which are able to be formed under the category of commonly available LSI steps.

In the first groove (24), or each of the first grooves (24), the aspect ratio (L1/W1) thereof which is the dimensional ratio of groove depth (L1) to groove width (W1) may preferably be 20 or more. The first groove(s) having the aspect ratio (L1/W1) of 20 or more enables the thick thermal-oxide layer to be formed in a depth of 20 μm or more at a low cost, and makes it possible to obtain a transmission loss reduction effect comparable to that of transmission lines formed on semi-insulating substrates like compound semiconductor substrates.

In the first groove (24), or each of the first grooves (24), the groove width (W1) thereof may preferably be 1 μm or less. The first groove(s) having the groove width of 1 μm or less makes the oxide film on the sidewall of the third groove have a thickness of 1 μm or less. This enables the thick thermal-oxide layer to be formed at a lower cost, and can more keep any crystal defects from occurring in the second device component formation region.

In the first and second embodiments of the semiconductor substrate manufacturing process of the present invention, an SOI (silicon on insulator) substrate may preferably be used as the semiconductor substrate, and the first and second grooves (24, 25) may preferably be so formed as to reach a buried oxide film layer (202) of the SOI substrate. Forming the first and second grooves to reach the buried oxide film layer when they are formed enables any thermal stress to be concentrated to the groove and polycrystalline semiconductor in the course of forming the second device components, and can more keep crystal defects and dislocation from occurring in the semiconductor substrate region where the second device components are formed, so that the second device components can be prevented from operating defectively.

In the first and second embodiments of the semiconductor substrate manufacturing process of the present invention, the first device components (5) may be passive components, and the second device components (Q1, Q2) may be active components. In particular, the present invention may preferably be applied to a case in which the passive components (5) are passive components that handle high-frequency signals.

Specific embodiments of the present invention are described below with reference to the accompanying drawings.

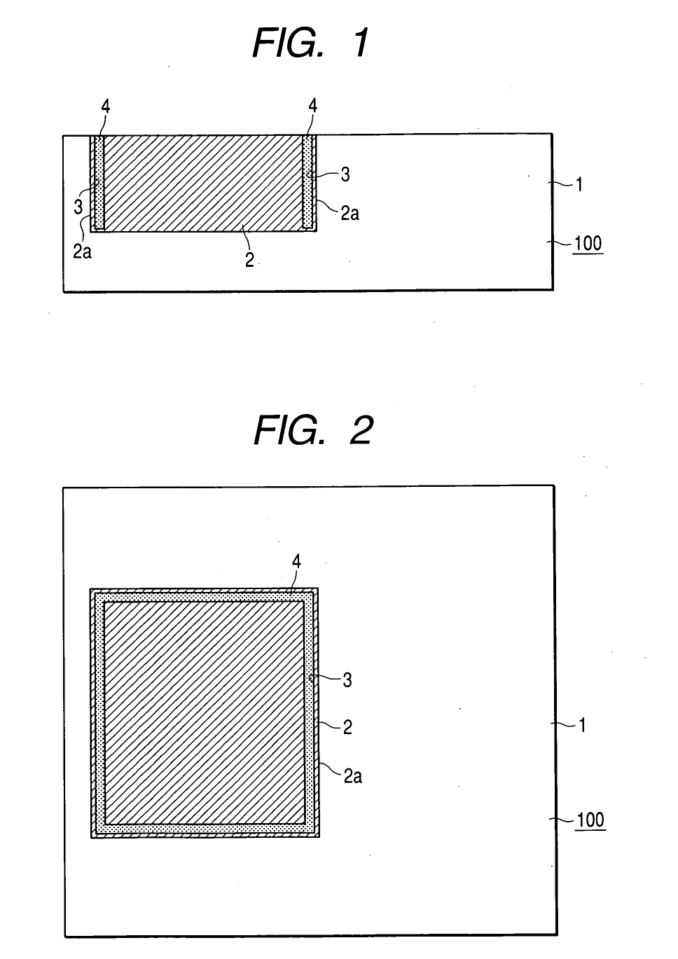

In one specific embodiment of the present invention, a semiconductor substrate 100 shown in FIGS. 1 and 2 is used. FIG. 1 is a longitudinal sectional view of the semiconductor substrate 100. FIG. 2 is a plan view of the semiconductor substrate 100. As shown in FIG. 1, a thick thermal-oxide layer 2 is formed on one surface side of a silicon substrate 1 in its partial region. The thermal-oxide layer 2 is, as shown in FIG. 2, in the shape of a square. As shown in FIGS. 1 and 2, a groove 3 is formed in the interior of the thermal-oxide layer 2. This groove 3 is positioned inward from a peripheral edge 2a of the thermal-oxide layer 2 and extends along the peripheral edge 2a. That is, the groove 3 is squarely cyclic in its plan shape. This groove 3 is packed with polycrystalline silicon (polycrystalline semiconductor) 4. More specifically, in the interior of the thermal-oxide layer 2, a wall 4 formed of polycrystalline silicon is buried in the vicinity of the peripheral edge 2a.

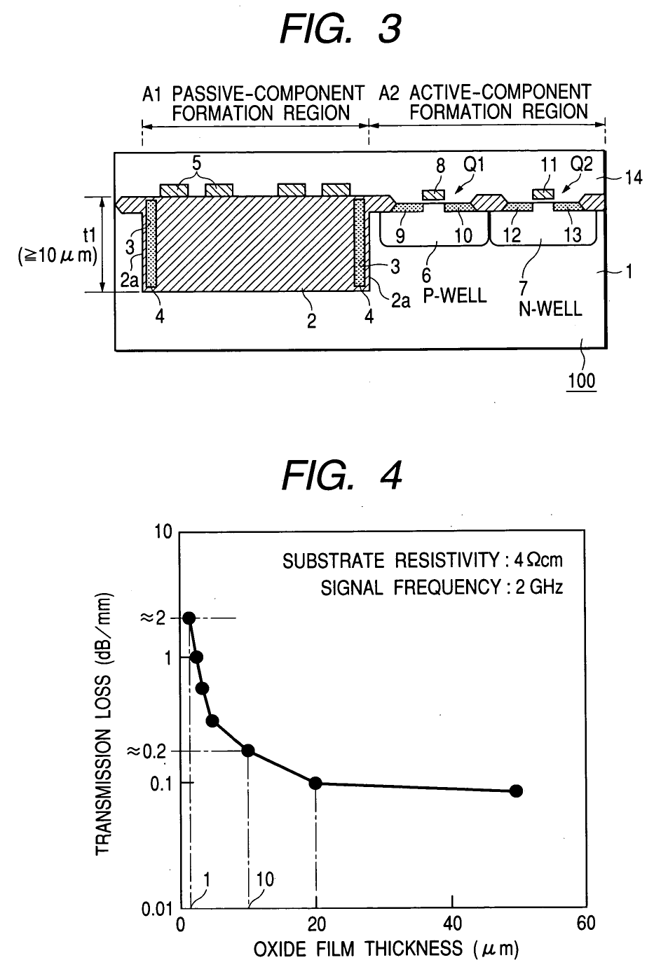

A high-frequency monolithic IC shown in FIG. 3 is formed using this semiconductor substrate 100. That is, in the present embodiment, the high-frequency monolithic IC is embodied as a semiconductor device. FIG. 3 is a longitudinal sectional view showing part of the high-frequency monolithic IC. In the semiconductor substrate 100 in this high-frequency monolithic IC, the thick thermal-oxide layer 2 serves as an insulating material on which passive components are disposed.

In the device shown in FIG. 3, transistors Q1 and Q2 as active components and inductors 5 as passive component are integrated, and circuits such as high-frequency oscillators, amplifiers and filters are made into one chip.

Stated in detail, in the device shown in FIG. 3, a thermal-oxide layer 2 of 10 μm or more in thickness is formed in a passive-component formation region A1 on a semiconductor substrate 1, and passive components spiral inductors 5 are formed thereon. In high-frequency circuits and the like, strong electromagnetic waves are produced right under the spiral inductors 5, and hence the thermal-oxide layer 2 may preferably be in a thickness t1 of 10 μm or more. In this example, it is in a thickness of 30 μm. A silicon thermal-oxide layer constituting the thermal-oxide layer 2 has a specific dielectric constant of about 3.9. The spiral inductors 5 are formed using a metallic material. In this example, aluminum (A1) is used, which is also a wiring material. However, the material is by no means limited to aluminum (A1). Cu, Au and so forth may also be used. Meanwhile, N-channel MOS transistors Q1 and P-channel MOS transistors Q2 are formed in an active-component formation region A1 on the semiconductor substrate 1.

FIG. 4 is a graph showing the results of simulation which show the relationship between signal transmission loss and oxide film layer thickness where the frequency f of signals applied to the wiring (signal line) disposed on the oxide film is set to be 2 GHz. In the simulation, the silicon substrate has a specific resistance of be 4 Ω·cm, and the line is formed of aluminum (A1) in a thickness of 1 μm and a width of 50 μm, at a distance of 30 μm from the ground wiring, and in a total length of 1 mm.

The following is seen from FIG. 4. The transmission loss becomes smaller with an increase in the oxide film thickness, where it can be about 1/10 of that in oxide film thickness=1 μm when the oxide film thickness is 10 μm or more. Also, the transmission loss stands substantially saturated when the oxide film thickness is 20 μm or more. The oxide film thickness at which the transmission loss comes saturated may differ depending on frequencies of signals, resistance values of lines, and sizes. In order to obtain a sufficient transmission loss reduction effect brought by the thick oxide film in a high-frequency region of 100 MHz or more, it is preferable to form the oxide film in a layer thickness of 10 μm or more. Moreover, when the oxide film is in a layer thickness of 20 μm or more, a transmission loss reduction effect is obtained which is comparable to that of transmission lines formed on semi-insulating substrates like compound semiconductor substrates.

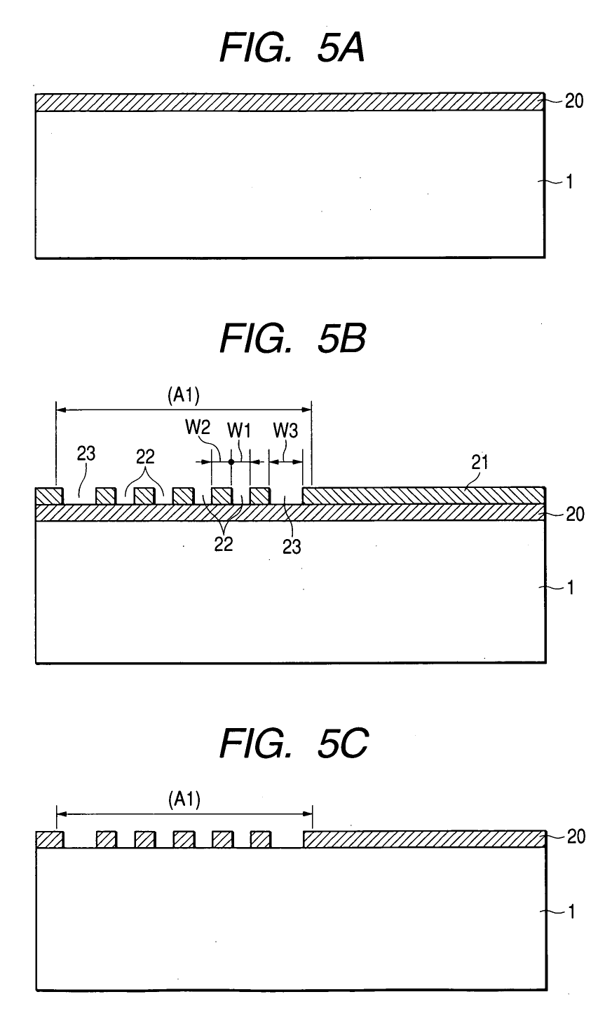

A process of manufacturing the semiconductor substrate for the monolithic IC is described below with reference to FIGS. 5A to 5C, 6A to 6C, 7A and 7B, and 8.

First, as shown in FIG. 5A, a silicon substrate 1 is prepared, and an oxide film (SiO₂) 20 is formed thereon. Further, as shown in FIG. 5B, a photoresist (the member denoted by reference numeral 21) is coated on the oxide film 20. Then, in a stated region, namely, a region where the thick thermal-oxide layer 2 is to be formed in the passive component formation region A1, a stripe-like groove pattern 22 with grooves of 1 μm or less, e.g., 0.8 μm each in width and, around it, a groove pattern 23 with a groove of 1 μm or more, e.g., 1.6 μm in width are formed, followed by exposure to make them open. Here, the width W2 of space between the grooves of the groove pattern 22 thus opened is set to be about 81.8% of the width (opening width) W1 of each groove of the groove pattern 22. For example, when the width W1 is 0.8 μm, the width (groove-to-groove distance) W2 is set to be about 0.65 μm.

Then, as shown in FIG. 5C, the oxide film 20 is etched at the groove patterns 22 and 23, and thereafter the resist 21 is removed to form a mask formed of the oxide film 20. This brings a state that the areas where the grooves of the silicon substrate 1 are to be formed are uncovered.

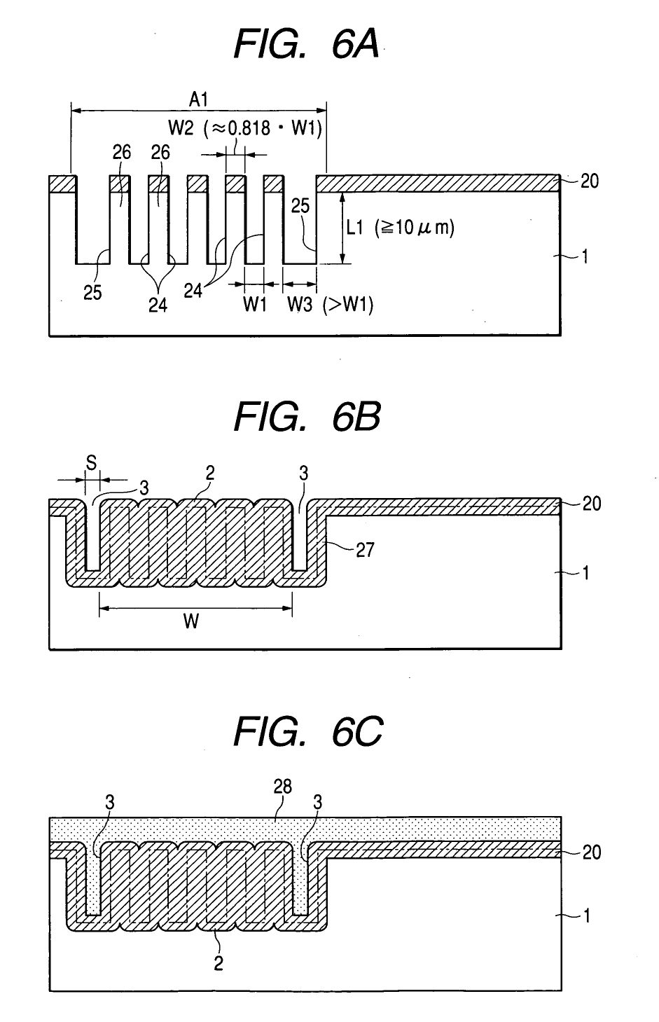

Subsequently, as shown in FIG. 6A and the plan view FIG. 8, a plurality of first grooves 24 of 10 μm or more each in depth are formed adjacently to each other, and, simultaneously, along the perimeter of a region where the first grooves 24 are to be formed, a second groove 25 having a larger groove width W3 than the groove width W1 the first grooves 24 each have are formed both in a region A1 in a semiconductor substrate 1 in which region the passive components 5 are to be disposed. In a broad sense, first grooves 24 of 10 μm or more each in depth and, along the perimeter of a region where the first grooves 24 are to be formed, a second groove 25 having a larger groove width W3 than the groove width W1 the first grooves 24 each have are simultaneously formed in the region A1 in the semiconductor substrate 1 in which region the passive components 5 are to be disposed. Stated in detail, the grooves are formed in the following way.

The silicon substrate 1 is etched by anisotropic etching to form the grooves 24 and 25 simultaneously. The width W1 of each first groove 24 is 1 μm or less, and the width W3 of the second groove 25 is more than 1 μm. The depth L1 of each of the grooves 24 and 25 is 10 μm or more as described above. In forming the grooves, reactive ion etching making use of a fluorine gas, in particular, anisotropic etching by high-density plasma etching is used. This enables formation of deep grooves each having an aspect ratio (L1/W1) of 10 or more which have sidewalls substantially vertical to the silicon substrate 1. Use of the etching process disclosed in Japanese Patent Application Laid-open No. 2000-29310 also enables formation of deep grooves each having an aspect ratio of 20 or more, where substantially vertical grooves of 20 μm or more each in depth can be formed even in a groove width of 1 μm or less. Here, silicon materials 26 lying between the stripe-like grooves 24 each have the shape of a thin wall with a width (thickness) W2 of about 81.8% of the groove width W1 and a height of 10 μm or more.

Then, as shown in FIG. 6B, a thermal-oxide film 27 is made to grow by thermal oxidation, from the inner surfaces of the first and second grooves 24 and 25 to make, in the first grooves 24, the grooves filled with a thermal-oxide film 27 to make the space of the adjoining first grooves 24 entirely into the thermal-oxide film 27, and form, in the second groove 25, the thermal-oxide film 27 on the bottom and sidewalls thereof leaving a third groove 3 therein. In a broad sense, the thermal-oxide film 27 is made to grow by thermal oxidation, from the inner surfaces of the first and second grooves 24 and 25 to make, in the first grooves 24, the grooves filled with a thermal-oxide film 27 and form, in the second groove 25, the thermal-oxide film 27 on the bottom and sidewalls thereof leaving a third groove 3 therein. Stated in detail, the thermal-oxide film 27 is formed in the following way.

The silicon substrate 1 standing as shown in FIG. 6A is subjected to oxidation treatment in an hydrogen-containing oxidizing atmosphere, e.g., in wet O₂, steam O₂ or an H₂—O₂ mixed combustion gas. Here, as for the silicon substrate 1 at its part in the grooves 24 and 25, with progress of oxidation the silicon layer in the interior of the substrate turns into silicon oxide for a portion corresponding to 45% of oxide film thickness, and expands outward from the bottom and sidewall surfaces of the silicon substrate 1 at that part having been not oxidized, for a portion corresponding to 55% of oxide film thickness. Hence, with progress of oxidation, the grooves 24 with a stripe pattern are filled on with the silicon oxide (thermal-oxide film 27) until oxide films having grown on the both-side sidewalls of each groove 24 come into contact with each other, whereupon the oxide films on sidewalls combine or join with each other, so that the insides of the grooves can completely be filled with the silicon oxide (thermal-oxide film 27). For example, when the width W1 of each groove 24 is 0.8 μm, the grooves can be filled therewith by carrying out oxidation treatment corresponding to treatment for growing an oxide film of about 0.73 μm in layer thickness.

The oxidation treatment for growing such an oxide film (thermal-oxide film 27) of 1 μm or less in layer thickness is used in usual LSI fabrication steps. A thick oxide layer can be formed through the step of oxidation carried out at 1,000° C. or more for several hours, without requiring any special step and at a lower cost than that in the prior art (Patent Literature 1). On the other hand, when an oxide film is required to be 2 μm or more in thickness, the step of oxidation carried for 10 hours or more is required, resulting in a high cost and also a high possibility of causing crystal defects in the silicon region.

When the groove with W1 is much smaller, this oxidation treatment can be carried out in a shorter time to bring a cost reduction, and also the oxide film formed on the outermost peripheral edge 2a can be made small in thickness and the crystal defects in the silicon region can be more kept from being caused.

In the course where the oxide films having grown on the sidewalls of each first groove 24 come into contact with each other and the oxide films on sidewalls combine or join with each other, the participation of hydrogen is necessary, and hence the oxidation treatment is carried out in the hydrogen-containing oxidizing atmosphere as described above. However, this hydrogen-containing oxidizing atmosphere may be present only immediately before the oxide films on sidewalls come into contact with each other and until the first grooves 24 are completely filled with the oxide. In the time other than the above, the atmosphere may be a hydrogen-free oxidizing atmosphere such as dry O₂.

The thin-wall-shaped silicon materials 26 in the region where the stripe-like first grooves 24 have been formed are, when the width (wall thickness) W2 is about 81.8% of the groove width W1, also all oxidized as a result of the above oxidation treatment to come into silicon oxide at the same time the insides of the first grooves 24 have completely been filled with the oxide. Thus, the thermal-oxide layer 2 of 10 μm or more in thickness can be formed over the whole region where the stripe-like first grooves 24 have been formed.

In the vicinity of the substrate surface in the thick thermal-oxide layer 2, the oxidation proceeds in the direction falling at right angles with the surface (horizontal direction) of the silicon substrate 1, and hence the part where silicon has been present in the beginning comes into a swollen state, so that the surface stands microscopically uneven.

In addition, since the second groove 25 has a larger groove width W3 than the groove width W1 the first grooves 24 each have, the third groove 3 comes to stand left unpacked as a result of the thermal oxidation in the second groove 25. Its groove width S (FIG. 6B) is about 0.8 μm when the original groove width W3 (the width of each second groove 25) at the initial stage is 1.6 μm and the groove width W1 is 0.8.

This third groove 3 absorbs any dimensional difference produced in the horizontal direction of the substrate because of the difference in coefficient of thermal expansion between the silicon and the silicon oxide during the heat treatment. That is, it absorbs the difference in coefficient of thermal expansion between the oxide film and the silicon substrate when the insides of the first grooves 24 are filled on. This enables reduction of the stress applied to the silicon substrate 1 during the heat treatment, and can keep any crystal defects and dislocation from occurring and the substrate (wafer) from warping.

Stated specifically in respect of this dimensional difference, it is calculated from the product (A×W×T) of the difference A in coefficient of thermal expansion between the silicon and the silicon (2.5×10⁻⁶−0.5×10⁻⁶=2.0×10⁻⁶/° C.), the maximum width W of the thermal-oxide layer portion that is formed around the first grooves 24 accompanying thermal oxidation, and the difference T in temperature between room temperature and maximum thermal oxidation treatment temperature. For example, when W is 300 μm and T is 1,100° C., A is 2.0×10⁻⁶/° C., and therefore a dimensional difference of 0.66 μm comes about as a whole. Hence, the groove width after the oxidation treatment of the second groove 25, i.e., the groove width S of the third groove 3 on one side as viewed in FIG. 6B must be so kept as to be left by 0.33 (=0.66/2) μm or more.

Thus, where the groove width of each of the first grooves 24 is represented by W1, the groove width of the second groove 25 by W3, the difference in coefficient of thermal expansion between the silicon substrate 1 and the thermal oxide thereof by A, the maximum width of the thermal-oxide layer portion 2 that is formed around the first grooves 24 accompanying thermal oxidation by W, and the difference in temperature between room temperature and maximum thermal oxidation treatment temperature by T, these may preferably satisfy the following expression:
W3>{(A·W·T)/2}+W1.
This enables the third groove 3 to absorb any dimensional difference produced in the horizontal direction of the substrate because of the difference in coefficient of thermal expansion between the silicon and its oxide during the heat treatment, to reduce the stress applied to the silicon substrate 1 during the heat treatment, and can keep any crystal defects and dislocation from occurring and the substrate (wafer) from warping. That is, the third groove 3 absorbs the difference in coefficient of thermal expansion between the thermal-oxide layer and the silicon substrate when the insides of the first grooves 24 are filled on. This can keep the silicon substrate 1 from warping, because any excess stress is not applied to the part of the silicon substrate 1.

Incidentally, as to the oxidation treatment in this step, what is shown is an example in which the treatment is carried out in the state the oxide film (mask material) 20 formed in the step shown in FIG. 5A is left unremoved. The oxidation treatment may also be carried out after the oxide film (mask material) 20 has been removed by etching before the oxidation treatment in the step shown in FIG. 6B. The oxide film (mask material) 20 may also be a film comprising a nitride film, where the oxidation treatment in the step shown in FIG. 6 which is carried out in the state the mask material 20 is left unremoved enables the thermal-oxide film 27 to be formed only on the inner surfaces of the grooves 24 and 25, so that the unevenness of the surface of the thick thermal-oxide layer 2 can be made small.

After the groove formation step shown in FIG. 6A, depending on etching conditions, the surfaces of the grooves 24 and 25 formed may have microscopic unevenness produced because of damage at the time of etching or the grooves 24 and 25 may have sharp edges at their uppermost corners. Hence, the thermal-oxide film 27 may non-uniformly grow on the groove surfaces in the step shown in FIG. 6B, so that the insides of the first grooves 24 may incompletely be filled with the oxide, and hollows may remain. Such hollows may be left as they are, as long as they do not interfere with the post-step LSI process. However, in some cases, a chemical solution used on the way of processing remain in the hollows to serve as a pollution source, or there is a possibility that the hollows expand during heat treatment to break. Accordingly, a step may be added which is the step of shaping the grooves to have shapes that may make the grooves readily fillable with the oxide, such as a sacrificial oxidation step. Also, the heat treatment may preferably be carried out at a temperature of 965° C. or above. The heat treatment at this temperature or above enables the thermal-oxide film 27 to be formed at a low stress to the silicon substrate 1 in virtue of the effect of viscosity flow of the oxide film in the step of oxidation, and also makes the first grooves 24 well fillable with the oxide.

In the oxidation treatment in the step shown in FIG. 6B, in the case when the grooves 24 and 25 have large aspect ratios, no oxidizing atmosphere may extend up to the groove bottoms and no oxidation may proceed there, because the grooves 24 and 25 stand filled with the atmosphere before oxidation treatment (e.g., air, and inert atmosphere such as nitrogen and argon). In such a case, the substrate may be inserted to vacuum before the oxidation treatment, and thereafter may be inserted to an atmosphere of oxygen to make the insides of the grooves 24 and 25 filled with oxygen.

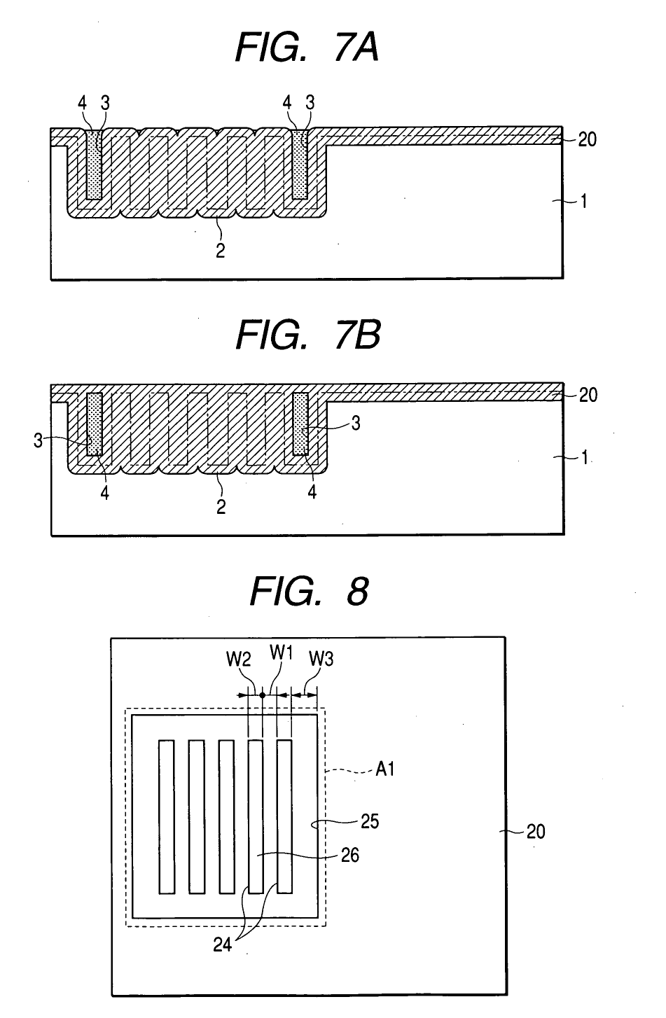

Next, the third groove 3 is packed with polycrystalline silicon 4 through the steps shown in FIGS. 6C, 7A and 7B. First, as shown in FIG. 6C, a polycrystalline semiconductor polycrystalline silicon 28 is deposited on the silicon substrate 1 in a thickness of about 1 μm by, e.g., LP-CVD to provide (to fill) the inside of the third groove 3 with the polycrystalline silicon. Any concavities on the surface of the thermal-oxide layer 2 may also be filled with the polycrystalline silicon by depositing it (by filling the concavities with the polycrystalline silicon), to make the surface substantially flat. Moreover, even in the case when the inside of the first grooves 24 is incompletely be filled with the oxide and hollows have remained, the polycrystalline silicon can fill out the hollows, having the effect of eliminating any contamination on the way of processing and any possibility of break of the substrate.

Subsequently, as shown in FIG. 7A, the polycrystalline silicon 28 having been deposited at the surface portion of the silicon substrate 1 is removed by etching, e.g., by reactive ion etching until the thermal-oxide film 27 on the surface other than the region where the thick thermal-oxide layer 2 is to be formed comes uncovered. Thus, excess polycrystalline silicon 28 on the surface is removed to afford a form in which the polycrystalline silicon remains only in the surface concavities of the thick thermal-oxide layer 2 and in the third groove 3 on the outer peripheral side of the former.

Next, as shown in FIG. 7B, the silicon substrate 1 is subjected to treatment to oxidize the polycrystalline silicon having remained in the surface concavities of the thermal-oxide layer 2. That is, the polycrystalline silicon (28) having remained in the surface concavities of the silicon substrate 1 is thermally oxidized. Having finished such a step, the thick thermal-oxide layer (thick insulating-material layer) 2 of 10 μm or more is formed in the preset region. Also, since the polycrystalline silicon having remained in the concavities of the surface portion of the thick thermal-oxide layer 2 undergoes volumetric expansion when it is oxidized, the surface is further flattened. The thick thermal-oxide layer 2 thus formed has a height substantially equal to the height of the silicon substrate surface, and also the polycrystalline silicon filled in the concavities can almost be oxidized. Hence, the thermal-oxide layer 2 can have a flat surface and the thickness of 10 μm or more.

The surface of the 10 μm or more thick thermal-oxide layer 2 thus formed is substantially flat and has sufficient mechanical strength. Hence, the monolithic IC as shown in FIG. 3 may be formed on this semiconductor substrate by a usual LSI process, i.e., the active components Q1 and Q2 (MOS transistors) may be formed on the silicon substrate 1, and the passive components (spiral inductors) 5 on the thermal-oxide layer 2. That is, a P-well region 6 and an N-well region 8 are formed at the surface layer portion of the silicon substrate 1, and also a gate electrode 8 is disposed on the P-well region 6 via a gate insulating film, and further a source region 9 and a drain region 10 are formed. Similarly, a gate electrode 11 is disposed on the N-well region 7 via a gate insulating film, and also a source region 12 and a drain region 13 are formed. Thereafter, metal wirings having the passive components (spiral inductors) 5 are formed, and further a passivation film 14 is formed on the substrate surface.

Here, in usual LSI processes, in particular, in the course of forming active components, the step of heat treatment at a high temperature of 800° C. or above is repeated many times. However, the polycrystalline silicon 4 can deform to absorb any dimensional difference produced in the horizontal direction of the substrate because of the difference in coefficient of thermal expansion between the silicon and the silicon oxide during the heat treatment. This enables reduction of the stress applied to the silicon substrate 1 during the heat treatment, and can keep any crystal defects and dislocation from occurring and the substrate (wafer) from warping. Then, since the silicon substrate 1 can be made to have low crystal defects and low dislocation, the active components can be prevented from operating defectively, and the active components can be formed at positions close to the thermal-oxide layer 2. This enables materialization of highly integrated high-frequency monolithic IC with less dead spaces. Also, device components can be formed without changing existing LSI fabrication processes, so that a high-performance high-frequency monolithic IC can be materialized which is inexpensive and suited for mass production.

Thus, in the present embodiment, the semiconductor substrate 100 as shown in FIG. 3 is the semiconductor substrate for use in a semiconductor device in which passive components 5 (which handle high-frequency signals) as first device components are disposed on an insulating material and active components Q1, Q2 as second device components are fabricated, and in which the thermal-oxide layer 2 of 10 μm or more in thickness is formed in the region A1 where the passive components are to be disposed, and the groove 3 packed with the polycrystalline semiconductor 4 is formed at an inward position from the peripheral edge 2a of the thermal-oxide layer 2 and along the same peripheral edge 2a. Hence, this thick thermal-oxide layer enables device components to exhibit their functions sufficiently. Stated specifically, parasitic capacitance and parasitic resistance in respect to the passive components (spiral inductors) 5 can sufficiently be reduced. Also, since the passive components 5 are not on any suspended wiring structure, sufficient mechanical strength can be obtained. Still also, the groove 3 packed with a polycrystalline silicon 4 is formed at an inward position from, and along, the peripheral edge 2a of the thermal-oxide layer 2. Hence, the polycrystalline silicon 4 serves as a layer that absorbs thermal stress applied in the step of forming the active components Q1 and Q2, and hence this can keep the substrate from warping, and any crystal defects and dislocation from occurring, so that the active components Q1 and Q2 can be prevented from operating defectively. This can lessen dead spaces, and materialize highly integrated circuits.

In each first groove 24 as shown in FIG. 6A, when the aspect ratio (L1/W1) thereof which is the dimensional ratio of groove depth L1 to groove width W1 is 10 or more, the thick thermal-oxide layer 2 can be formed in a depth of 10 μm or more at a low cost by the step of thermal oxidation of films of about 1 μm in layer thickness which are able to be formed under the category of commonly available LSI steps. Also, in each first groove 24, when the aspect ratio (L1/W1) thereof which is the dimensional ratio of groove depth L1 to groove width W1 is 20 or more, the thick thermal-oxide layer 2 can be formed in a depth of 20 μm or more at a low cost, and a transmission loss reduction effect is obtained which is comparable to that of transmission lines formed on semi-insulating substrates like compound semiconductor substrates.

In each first groove (24), when the groove width W1 thereof is 1 μm or less, the oxide film on the sidewall of the third groove 3 can be made to have a thickness of 1 μm or less. This enables formation of the thick thermal-oxide layer at a lower cost, and can more keep any crystal defects from occurring in the second device component formation region.

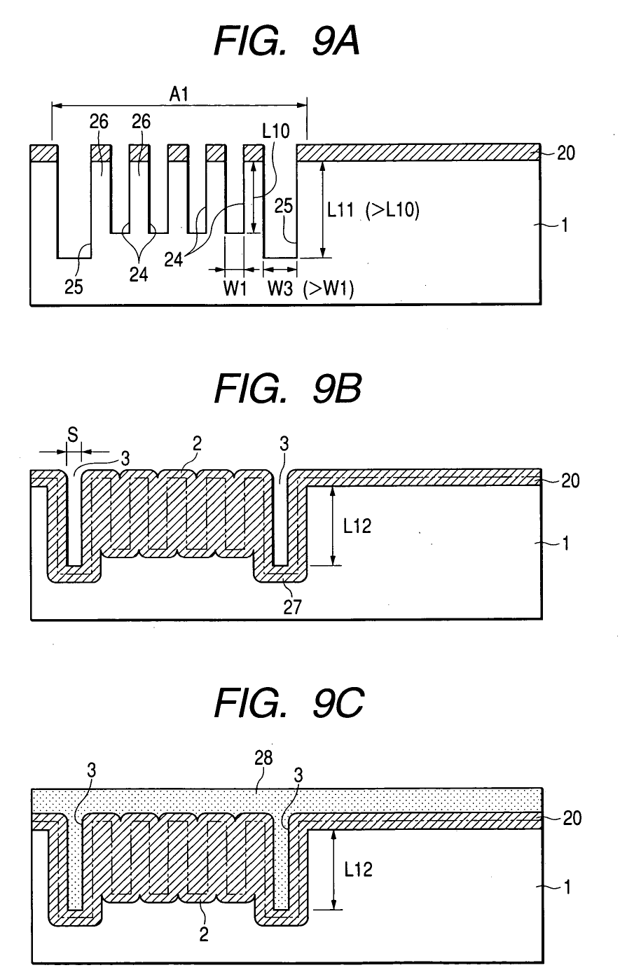

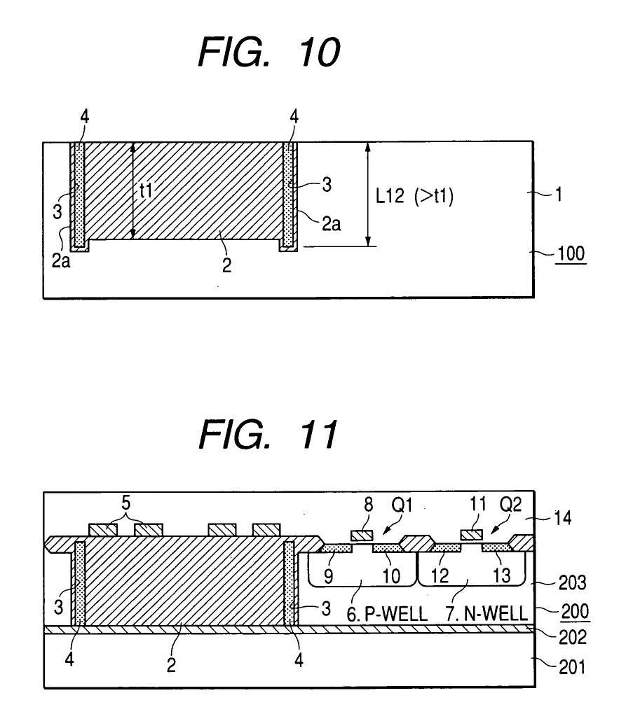

In the step of forming the grooves 24 and 25 as shown in FIG. 6A, the groove depth can be made larger at a place having a larger groove width, depending on etching conditions. Utilizing this, in the step of simultaneously forming first grooves 24 and a second groove 25 as shown in FIG. 9A in place of FIG. 6A, the second groove 25 is formed in a depth Lll which is larger than the depth L10 of each first groove 24. Then, as shown in FIGS. 9B and 9C, the thermal oxidation and the deposition of the polycrystalline silicon 28 are carried out. Through these steps, as shown in FIG. 10, the polycrystalline silicon 4 with which the third groove 3 has been packed may be made to have a depth L12 which is larger than the thickness t1 of a thermal-oxide layer 2 formed by thermally oxidizing the first grooves 24 and filling them with the oxide having grown. That is, the width L12 of the third groove 3 packed with the polycrystalline silicon 4 may be made larger than the thickness t1 of the thermal-oxide layer 2. Stated in detail, the depth L12 of the third groove 3 is made larger than the thickness t1 of the thermal-oxide layer 2 at its part other than the region where the third groove 3 has been formed.

With such construction, the thermal stress (difference in coefficient of thermal expansion between the oxide film and the silicon substrate) can effectively be absorbed up to a further lower part of the thick thermal-oxide layer 2 region in the step of forming device components on the semiconductor substrate 100 (LSI process). Hence, this can much more keep any crystal defects and dislocation from occurring in the interior of the substrate and the substrate (safer) from warping. Also, when as shown in FIG. 9A the depth L11 of the second groove 25 is larger than the depth of each first groove 24, the difference in coefficient of thermal expansion between the oxide film and the silicon substrate can effectively be absorbed up to a further lower part of the thick thermal-oxide layer 2 region in the step of manufacturing the semiconductor substrate 100. Hence, this can much more keep any crystal defects and dislocation from occurring and the substrate (safer) from warping.

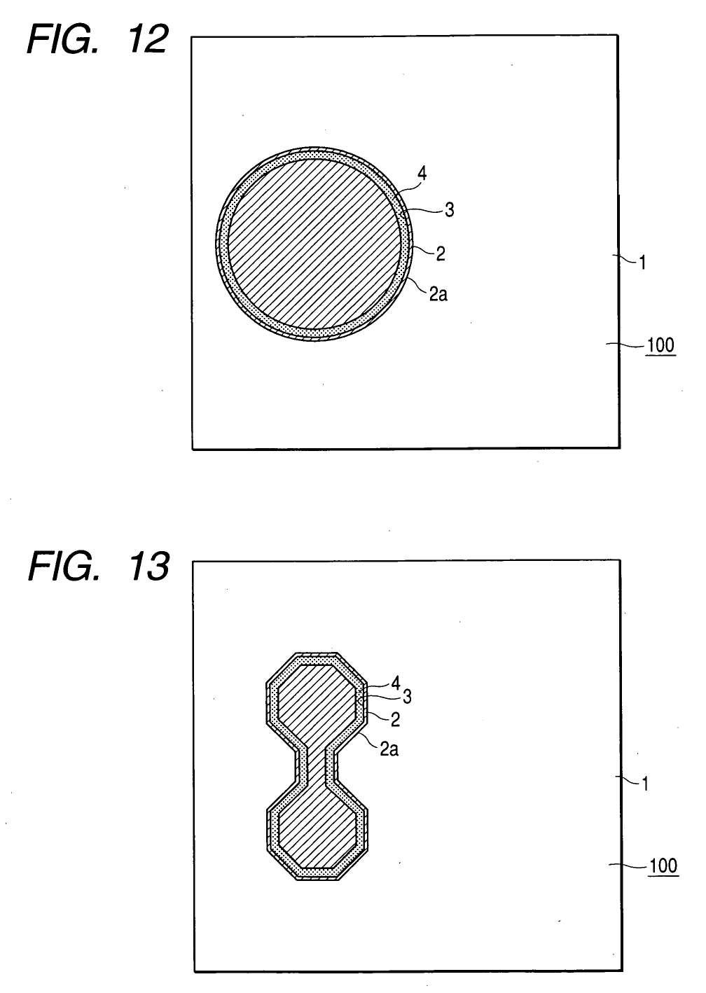

In what have so far been described, cases have been shown in which a commonly available silicon substrate is used. Instead, an SOI (silicon on insulator) substrate 200 as shown in FIG. 11 may be used as the substrate. FIG. 11 is a longitudinal sectional view showing part of a monolithic IC in which the SOI substrate is applied. In the device shown in FIG. 11, a single-crystal silicon layer 203 of 10 μm or more in thickness is formed on a silicon substrate 201 via an oxide film layer 202 of about 1 μm in thickness. A thermal-oxide layer 2 is also formed in the single-crystal silicon layer 203 in its partial region. This thermal-oxide layer 2 reaches a buried oxide film layer 202. To that end, in the step shown in FIG. 6A, the substrate is etched until the grooves 24 and 25 reach the buried oxide film layer 202. More specifically, third grooves 24 and 25 which reach the buried oxide film layer 202 of the SOI substrate are formed in the step of forming the grooves.

With such construction, the silicon layer in the region where the thermal-oxide layer is to be formed and the silicon layer in the region other than that can completely be separated by oxides. Hence, any thermal stress can be concentrated to the outer-peripheral groove 3 and polycrystalline silicon 4 in the subsequent step of forming the thick thermal-oxide layer and in the course of forming the active components. This can more keep crystal defects and dislocation from occurring in the semiconductor substrate region where the active components are formed, so that the active components can be prevented from operating defectively. Stated more specifically, in the device shown in FIG. 3, any defects produced at a lower part of the thermal-oxide layer 2 extend in the horizontal (right-and-left) direction, and there is a possibility of affecting the transistors Q1 and Q2 adversely. Compared with this, in the device shown in FIG. 11, such a problem is avoided in virtue of the presence of the buried oxide film layer 202.

In what have so far been described, cases have been shown in which transistors are used as the active components and the inductors as the passive components. Instead, the present invention may also be applied to cases in which diodes and the like are used as the active components and metal wirings, resistors, capacitors and the like as the passive components.

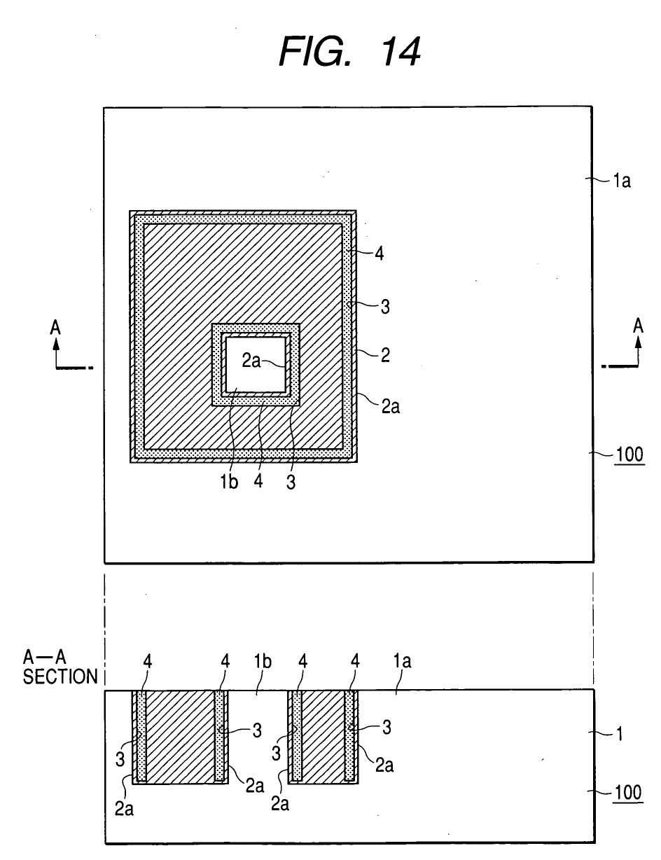

Incidentally, in the substrates shown in FIGS. 2 and 8, the pattern of the thick thermal-oxide layer 2 has a square shape. Its pattern is by no means limited to the square shape, and any pattern may be used. Stated specifically, it may be circular as shown in FIG. 12, or may be complicately polygonal or so. Besides, as shown in FIG. 14, within the silicon substrate 1 the thermal-oxide layer 2 may be formed in a squarely cyclic shape as its plan structure. That is, it may be formed in such a pattern that the single-crystal silicon la is present around the squarely cyclic thermal-oxide layer 2 and also a single-crystal silicon island 1b is present inside the squarely cyclic thermal-oxide layer 2. In this case, third grooves 3 packed with polycrystalline silicon are formed at boundary portions between the thermal-oxide layer 2 and single-crystal silicon regions (1a, 1b), and at inward and outward positions from outer and inner peripheral edges 2a, respectively, of the thermal-oxide layer 2 and along the same peripheral edges 2a.

In what have so far been described, cases have also been shown in which the semiconductor substrate according to the present invention is applied to the high-frequency monolithic IC. That is, it is the semiconductor substrate for use in the semiconductor device in which the passive components (inductors) 5 as first device components are disposed on the thermal-oxide layer 2 and the active components (transistors) Q1, Q2 as second device components are fabricated. Without limitation thereto, the semiconductor substrate of the present invention may be applied in the following way:

For example, it may be applied to an IC for a microprocessor with a clock frequency of 1 GHz or more. Stated specifically, microprocessor components (such as transistors) as second device components are fabricated on the silicon layer and also wirings are disposed as first device components on the thermal-oxide layer 2.

Besides, it may be applied to an IC having a power component which requires a high breakdown strength of 1,000 volts or more. Stated specifically, power components are fabricated as second device components on the silicon layer and the thermal-oxide layer 2 is formed to achieve isolation of device components, and also wirings are disposed as first device components on the thermal-oxide layer 2. In this case, the thick thermal-oxide layer 2 enables improvement in breakdown strength.

Besides, it may be applied to an IC having a sensor component which requires thermal insulation to the substrate. Stated specifically, sensor components are disposed as first device components on the thermal-oxide layer 2 and also sensor signal processing circuit components (amplifier components, A/D conversion components) as second device components are fabricated at the former's side. In this case, the thick thermal-oxide layer 2 enables improvement in heat barrier performance.

1. A semiconductor substrate for use in a semiconductor device in which first device components are disposed on an insulating material and second device components are fabricated, wherein;
a thermal-oxide layer of 10 μm or more in thickness is formed in a region where the first device components are to be disposed, and a groove packed with a polycrystalline semiconductor is formed at an inward position from the peripheral edge of the thermal-oxide layer and along the same peripheral edge.

2. The semiconductor substrate according to claim 1, wherein said groove packed with a polycrystalline semiconductor has a depth larger than the thickness of said thermal-oxide layer.

3. The semiconductor substrate according to claim 1, wherein said semiconductor substrate comprises a silicon-on-insulator substrate, and said thermal-oxide layer reaches a buried oxide film layer of the silicon-on-insulator substrate.

4. The semiconductor substrate according to claim 1, wherein said first device components comprise passive components, and said second device components comprise active components.

5. The semiconductor substrate according to claim 4, wherein said passive components comprise passive components that handle high-frequency signals.

6. A process for manufacturing a semiconductor substrate for use in a semiconductor device in which first device components are disposed on an insulating material and second device components are fabricated; the process comprising the steps of:
simultaneously forming, in a region in a semiconductor substrate in which region the first device components are to be disposed, a first groove of 10 μm or more in depth and, along the perimeter of a region where the first groove is to be formed, a second groove having a larger groove width than the groove width the first groove has;
making a thermal-oxide film grow by thermal oxidation, from the inner surfaces of the first and second grooves to make, in the first groove, the groove filled with the thermal-oxide film and form, in the second groove, the thermal-oxide film on the bottom and sidewalls thereof leaving a third groove therein; and
packing the third groove with a polycrystalline semiconductor.

7. A process for manufacturing a semiconductor substrate for use in a semiconductor device in which first device components are disposed on an insulating material and second device components are fabricated; the process comprising the steps of:
simultaneously forming, in a region in a semiconductor substrate in which region the first device components are to be disposed, a plurality of first grooves of 10 μm or more each in depth in the state that they stand adjacent to each other, and, along the perimeter of a region where the first grooves are to be formed, a second groove having a larger groove width than the groove width the first grooves each have;
making a thermal-oxide film grow by thermal oxidation, from the inner surfaces of the first and second grooves to make, in the first grooves, the grooves filled with the thermal-oxide film and form, in the second groove, the thermal-oxide film on the bottom and sidewalls thereof leaving a third groove therein; and
packing the third groove with a polycrystalline semiconductor.

8. The semiconductor substrate manufacturing process according to claim 6, wherein, in the step of forming a first groove and a second groove simultaneously, said second groove is formed in a depth larger than the depth of said first groove.

9. The semiconductor substrate manufacturing process according to claim 6, wherein the step of packing the third groove with a polycrystalline semiconductor comprises depositing a polycrystalline semiconductor on said semiconductor substrate to provide the polycrystalline semiconductor in the third groove, thereafter removing an excess polycrystalline semiconductor deposited at the surface portion of said semiconductor substrate, and then thermally oxidizing the polycrystalline semiconductor having remained in surface concavities of said semiconductor substrate.

10. The semiconductor substrate manufacturing process according to claim 6, wherein, where the groove width of said first groove is represented by W1, the groove width of said second groove by W3, the difference in coefficient of thermal expansion between said semiconductor substrate and the thermal oxide thereof by A, the maximum width of a thermal-oxide film portion that is formed around said first groove accompanying thermal oxidation by W, and the difference in temperature between room temperature and maximum thermal oxidation treatment temperature by T, these satisfy the following expression:
W3>{(A·W·T)/2}+W1.

11. The semiconductor substrate manufacturing process according to claim 6, wherein, in said first groove, the aspect ratio L1/W1 thereof which is the dimensional ratio of groove depth L1 to groove width W1 is 10 or more.

12. The semiconductor substrate manufacturing process according to claim 6, wherein, in said first groove, the aspect ratio L1/W1 thereof which is the dimensional ratio of groove depth L1 to groove width W1 is 20 or more.

13. The semiconductor substrate manufacturing process according to claim 6, wherein, in said first groove, the groove width W1 thereof is 1 μm or less.

14. The semiconductor substrate manufacturing process according to claim 6, wherein a silicon-on-insulator substrate is used as said semiconductor substrate, and said first and second grooves are so formed as to reach a buried oxide film layer of the silicon-on-insulator substrate.

15. The semiconductor substrate manufacturing process according to claim 6, wherein said first device components comprise passive components, and said second device components comprise active components.

16. The semiconductor substrate manufacturing process according to claim 6, wherein said said passive components comprise passive components that handle high-frequency signals.

17. The semiconductor substrate manufacturing process according to claim 7, wherein, in the step of forming first grooves and a second groove simultaneously, said second grooves are each formed in a depth larger than the depth of said first groove.

18. The semiconductor substrate manufacturing process according to claim 7, wherein the step of packing the third groove with a polycrystalline semiconductor comprises depositing a polycrystalline semiconductor on said semiconductor substrate to provide the polycrystalline semiconductor in the third groove, thereafter removing an excess polycrystalline semiconductor deposited at the surface portion of said semiconductor substrate, and then thermally oxidizing the polycrystalline semiconductor having remained in surface concavities of said semiconductor substrate.

19. The semiconductor substrate manufacturing process according to claim 7, wherein, where the groove width of each of said first grooves is represented by W1, the groove width of said second groove by W3, the difference in coefficient of thermal expansion between said semiconductor substrate and the thermal oxide thereof by A, the maximum width of a thermal-oxide film portion that is formed around the first groove accompanying thermal oxidation by W, and the difference in temperature between room temperature and maximum thermal oxidation treatment temperature by T, these satisfy the following expression:
W3>{(A·W·T)/2}+W1.

20. The semiconductor substrate manufacturing process according to claim 7, wherein, in each of said first grooves, the aspect ratio L1/W1 thereof which is the dimensional ratio of groove depth L1 to groove width W1 is 10 or more.

21. The semiconductor substrate manufacturing process according to claim 7, wherein, in each of said first grooves, the aspect ratio L1/W1 thereof which is the dimensional ratio of groove depth L1 to groove width W1 is 20 or more.

22. The semiconductor substrate manufacturing process according to claim 7, wherein, in each of said first grooves, the groove width W1 thereof is 1 μm or less.

23. The semiconductor substrate manufacturing process according to claim 7, wherein a silicon-on-insulator substrate is used as said semiconductor substrate, and said first and second grooves are so formed as to reach a buried oxide film layer of the silicon-on-insulator substrate.

24. The semiconductor substrate manufacturing process according to claim 7, wherein said first device components comprise passive components, and said second device components comprise active components.

25. The semiconductor substrate manufacturing process according to claim 7, wherein said said passive components comprise passive components that handle high-frequency signals.
